(19) United States
(12) Patent Application Publication
(10) Pub. No.: US 2022/0260924 A1
(43) Pub. Date: Aug. 18, 2022

(54) PROJECTION EXPOSURE APPARATUS FOR SEMICONDUCTOR LITHOGRAPHY

(71) Applicant: Carl Zeiss SMT GmbH, Oberkochen (DE)

(72) Inventor: Toralf Gruner, Aalen-Hofen (DE)

(21) Appl. No.: 17/735,681

(22) Filed: May 3, 2022

Related U.S. Application Data
(63) Continuation of application No. PCT/EP2020/080875, filed on Nov. 4, 2020.

(30) Foreign Application Priority Data
Nov. 7, 2019 (DE) 102019217185.0

(51) Int. Cl. G03F 7/20; G02B 7/00; G02B 27/00

(52) U.S. Cl. CPC G03F 7/70308; G02B 27/0025; G02B 7/008; G03F 7/70891

(57) ABSTRACT

A projection exposure apparatus for semiconductor lithography includes an optical correction element and an electromagnetic heating radiation source for at least partly irradiating an optically active region of the correction element with electromagnetic heating radiation. The optical correction element is provided with at least one electrical heating element outside the optically active region.

### CROSS-REFERENCE TO RELATED APPLICATIONS

The present application is a continuation of, and claims benefit under 35 USC 120 to, international application PCT/EP2020/080875, filed Nov. 4, 2020, which claims benefit under 35 USC 119 of German Application No. 10 2019 217 185.0, filed Nov. 7, 2019. The entire disclosure of these applications are incorporated by reference herein.

### FIELD

The disclosure relates to a projection exposure apparatus for semiconductor lithography.

### BACKGROUND

Projection exposure apparatuses for semiconductor lithography are used for producing extremely fine structures, in particular on semiconductor components or other microstructured component parts. The functional principle of the apparatuses is based on the production of extremely fine structures down to the nanometer range by way of generally reducing imaging of structures on a mask, a so-called reticle, on an element to be structured, a so-called wafer, that is provided with photosensitive material. The minimum dimensions of the structures produced are typically directly dependent on the wavelength of the light used. Recently, light sources having an emission wavelength in the range of a few nanometers, for example between 1 nm and 30 nm, such as the region of 13.5 nm, have increasingly been used. The described wavelength range is also referred to as the EUV range.

Apart from the use of these systems, the microstructured component parts are also produced using commercially established systems having a wavelength of 193 nm. The introduction of the EUV range, and hence the possibility of being able to produce even smaller structures, can result in increasing demands with respect to the optical correction of the systems having a wavelength of 193 nm. At the same time the throughput is usually increased in order to increase economic viability, which typically results in greater thermal loading and hence increasing imaging aberrations with a thermal cause.

In order to correct the imaging aberrations it is possible to use, inter alia, manipulators including two plates arranged plane-parallel, the surfaces of which are heated by irradiation with electromagnetic heating radiation and which are cooled globally by a gas flow passing between the plane-parallel plates. The resultant locally adjustable temperature distribution over the plates is translated, by way of the temperature-dependent refractive index of the material used, such as quartz glass, for example, into a desired wavefront effect that compensates for imaging aberrations.

The international patent application WO 2010/133231 A1, which was filed by the present applicant and is hereby fully incorporated by reference, discloses such a manipulator having two plane-parallel plates, between which a cooling channel is embodied, through which flows a fluid embodied as a global heat sink, i.e. for dissipating heat. The local heating of the plates is brought about by irradiation with infrared light, the light beams being incident either on the surfaces of the cooling channel or on the plates, on the opposite outer sides thereof. The plates are locally heated by absorption of the light beams. Particularly in the edge region of the plates, irradiation may be possible only at a very shallow angle, which can result in poor absorption and hence insufficient heating of the edge regions.

### SUMMARY

The present disclosure seeks to provide an improved apparatus.

A projection exposure apparatus according to the disclosure for semiconductor lithography includes an optical correction element and a device for at least partly irradiating an optically active region of the correction element with electromagnetic heating radiation, wherein according to the disclosure the optical correction element is provided with at least one electrical heating element outside the optically active region. The optical correction mechanism can be arranged in an imaging optical unit of the projection exposure apparatus for example in order to correct imaging aberrations. The device can be lasers, for example, wherein the laser light can be guided via optical waveguides and can thus bring about an irradiation at one or more positions of the optical correction element. In this case, the electromagnetic heating radiation can irradiate the optical correction element from one of the side surfaces thereof, i.e. perpendicularly to the optical axis thereof, or on one of the optically active surfaces of the optical correction element. The radiation can be at least partly absorbed by the material of the optical correction element, which results in heating of the material. In this context, the optically active region should be understood to mean that region of the optical correction element which is impinged on by the used light, i.e. the light which is used for imaging structures of a reticle onto a wafer, during the operation of the projection exposure apparatus. The optically active region can vary depending on the operating mode, the maximum extent being defined by the optical design of the projection exposure apparatus.

In particular, the electrical heating element can be arranged exclusively outside the optically active region, such that no electrical heating element is situated in the optically active region.

The electrical heating element can include a resistance wire, wherein the resistance wire can have a thickness of at least 1 μm, such as at least 5 μm, for example at least 10 μm. As a result of the arrangement of the resistance wire outside the optically active region, the thickness and the height of the wire have no influence on the optical imaging and can be designed according to their effect, the electrical properties and producibility.

Furthermore, the electrical heating element can be arranged on a surface of the optical element. This can have the advantage that the electrical heating element does not obstruct an irradiation of the optically active region through the side surface of the optical correction element.

In addition, a plurality of electrical heating elements can be arranged on the optical correction element in such a way that locally different power densities of the heating power can be realized. This makes it possible to adapt the heating power of the electrical heating elements depending on the heating caused by the used light and by the irradiation of the optical correction element by the laser and thus to realize a predetermined temperature profile in the optical correction element.

In particular, a plurality of heating elements can have different electrical properties. The latter, in the case of a resistance wire, can concern the resistance of the wire, which can in turn be influenced by the diameter of the wire, the material of the wire or the geometric length per area of the wire. The length per area can be increased for example by meandering arrangement and small distances between the meanders of the resistance wire.

Furthermore, an open-loop/closed-loop control can be present which is suitable for controlling the plurality of heating elements in such a way that locally different power densities of the heating power can be realized.

In particular, at least one temperature sensor can be present which detects the temperature of the optical correction element. As a result, the desired electrical heating power can be determined on the basis of the detected temperature. The use of a plurality of temperature sensors can advantageously increase the accuracy and the speed of the correction.

In one variant of the disclosure, the optical correction element can include at least one plane-parallel plate. The plane-parallel plate itself has no optical effect apart from an offset of an image in the case of oblique transmission of radiation, such that it exhibits neutral behavior in the case of homogeneous temperature distribution and perpendicular transmission of radiation in an optical system.

In particular, the optical correction element can include two plane-parallel plates, between which a fluid channel can be embodied. By way of example, air can flow through the fluid channel, the temperature of the air expediently being less than that of the optical correction element, as a result of which the fluid can serve as a heat sink. Part of the heat that arises in the plane-parallel plates as a result of the irradiation by the used light, the laser and the heating by the electrical heating element in the edge region can thus be dissipated, and it is possible to set a temperature profile with at the same time thermodynamic equilibrium in the plate. The two plane-parallel plates can thus have a temperature profile impressed, without heat being emitted to the imaging device of the projection exposure apparatus in the process.

In this case, the plane-parallel plates can be arranged parallel to one another at a distance of between 2 mm and 50 mm. The distance can be dependent inter alia on the amount of fluid used to dissipate the heat or, in the case where both plane-parallel plates include electrical heating elements, on the optical effect thereof.

At least one plane-parallel plate can have a thickness of between 2 mm and 20 mm. The thickness can likewise be dependent on its optical effect, aspects in terms of manufacturing technology, desired mechanical stiffness, the heat capacity and also the desired correction effect of the optical correction element as a whole.

In addition, the material of the plane-parallel plates and the wavelength of the irradiation can be embodied such that an average absorption of the irradiation over the optically active region of at least 10 W, such as at least 50 W, for example at least 100 W, can be realized. Depending on the cooling capacity of the fluid which flows through between the plane-parallel plates, it is possible to increase the absorption and thus the amount of supplied heat in the optically active region. The optical correction element is expediently embodied such that the interfaces with respect to the imaging optical unit have a thermally neutral effect, that is to say that the power supplied by the irradiation and the electrical heating element(s) is not more than can be dissipated by the fluid flow and the mechanical linking of the plane-parallel plates. In this case, the heating power for generating the temperature profile in the plane-parallel plate can be independent of the thermally neutral power balance.

In particular, the material of the plane-parallel plates and the wavelength of the electromagnetic heating radiation can be embodied such that the absorptivity is between 10% and 20% of the incident power per 100 mm of material. As a result, it is possible to achieve an absorption and hence heating over the entire optical element at a maximum incident power of 100 watts, such as 60 watts. The shaping of the electromagnetic heating radiation and the variation of the absorption properties of the material make it possible to achieve a power input that is constant over the distance.

Furthermore, an electrical connection strip for contacting the electrical heating element can be present, and can run parallel to the fluid channel at least in sections. The connection strip connects the electrical supply to the individual electrical heating elements, which can all be connected to one side of the optical correction element for reasons of simplified accessibility and mounting.

In addition, at least two electrical heating elements, for example all the electrical heating elements, can be connected to a common ground line. This can have the advantage that there is no need to install a dedicated ground line for each electrical heating element.

### BRIEF DESCRIPTION OF THE DRAWINGS

Exemplary embodiments and variants of the disclosure are explained in greater detail below with reference to the drawing, in which:

FIG. 1 shows a basic illustration of a projection exposure apparatus in which the disclosure can be applied; and

FIG. 2 shows a basic detailed illustration of the disclosure.

### EXEMPLARY EMBODIMENTS

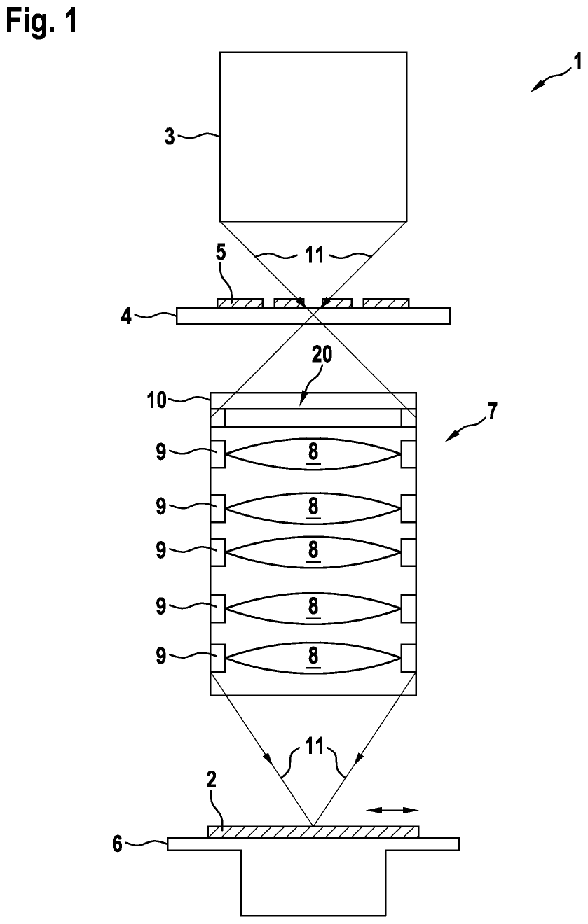

FIG. 1 illustrates an exemplary projection exposure apparatus 1 in which the disclosure can be applied. The projection exposure apparatus 1 serves for imaging structures on a substrate which is coated with photosensitive materials, and which generally consists predominantly of silicon and is referred to as a wafer 2, for the production of semiconductor components, such as computer chips. The projection exposure apparatus 1 in this case substantially includes an illumination device 3, a reticle stage 4 for receiving and exactly positioning a mask provided with a structure, a so-called reticle 5, by which the later structures on the wafer 2 are determined, a wafer stage 6 for holding, moving and exactly positioning the wafer 2 and an imaging device, to be specific a projection lens 7, with a plurality of optical elements 8, which are held by way of mounts 9 in a lens housing 10 of the projection lens 7. The basic functional principle in this case provides that an image of the structures introduced into the reticle 5 is projected onto the wafer 2; the imaging generally being on a reduced scale. The illumination device 3 provides a projection beam 11 in the form of electromagnetic radiation, which is used for the imaging of the reticle 5 on the wafer 2. A laser, a plasma source or the like can be used as the source of this radiation. Optical elements in the illumination device 3 are used to shape the radiation in such a way that, when it is incident on the reticle 5, the projection beam 11 has the desired properties with regard to diameter, polarization and the like. An image of the reticle 5 is produced by the projection beam 11 and transferred from the projection lens 7 onto the wafer 2 in an appropriately reduced form, as already explained above. In this case, the reticle 5 and the wafer 2 can be moved synchronously, so that images of regions of the reticle 5 are projected onto corresponding regions of the wafer 2 virtually continuously during a so-called scanning operation. The projection lens 7 has a multiplicity of individual refractive, diffractive and/or reflective optical elements 8, such as, for example, lens elements, mirrors, prisms, terminating plates and the like, wherein the optical elements 8 can be supplemented or replaced for example by an optical correction device 20 according to the disclosure.

The disclosure can likewise be used in an EUV apparatus, which is not illustrated. An EUV apparatus is set up in principle like the DUV apparatus 1 described above, wherein in an EUV apparatus predominantly mirrors can be used as optical elements and the light source of an EUV apparatus emits used radiation in a wavelength range of 5 nm to 100 nm, in particular 13.5 nm. In the case where the disclosure is used in an EUV apparatus, a mirror would then be heated outside its optically active region via an electrical heating element.

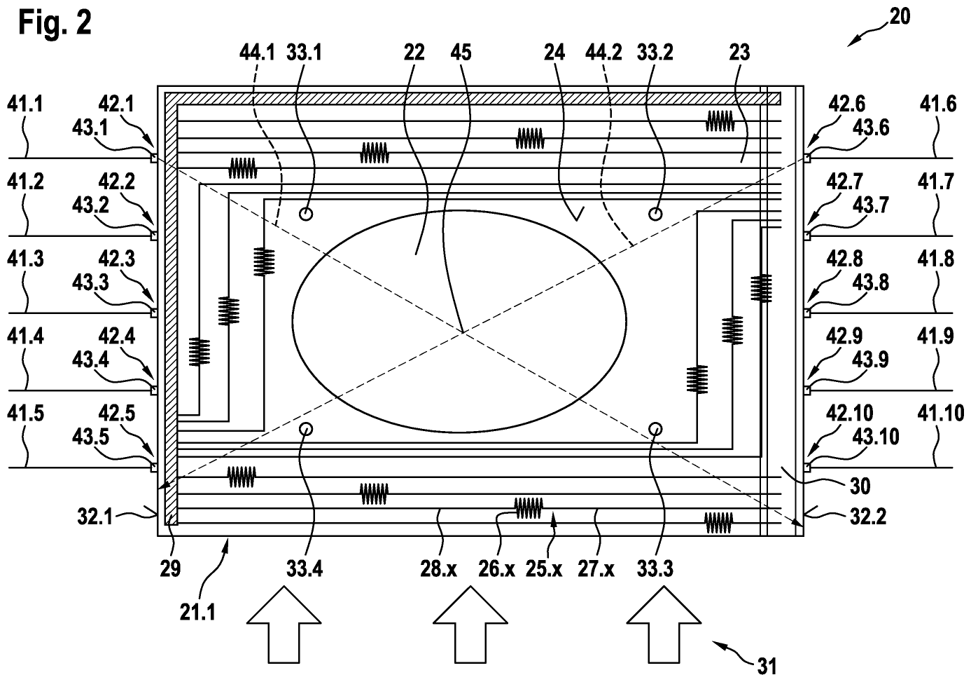

FIG. 2 shows a detailed illustration of the disclosure, illustrating a device embodied as a thermal manipulator 20 in a plan view. The manipulator 20 includes an optical element embodied from two plane-parallel plates 21.x. Only the lower 21.1 of the two plane-parallel plates 21.x, which are embodied functionally identically, is illustrated in FIG. 2, the illustration showing a plan view of the surface 24 of the plane-parallel plate 21.1 from above in the direction of the used light. The plane-parallel plate 21.1 includes an optically active region 22, which is impinged on by used radiation (not illustrated) of the projection exposure apparatus. Furthermore, the optically active region 22 is irradiated by electromagnetic heating radiation embodied as laser beams 44.x, the irradiation being coupled into the plane-parallel plate 21.1 through the side surfaces 32.x thereof. The laser beams 44.x are emitted by one or more lasers (not illustrated) and are guided via optical waveguides 41.x to the input coupling points 42.x at the side surfaces 32.x of the plane-parallel plate 21.1. Input coupling optical units 43.x embodied as spherical lens elements, for example, are arranged at the input coupling points 42.x, and shape the laser beams 44.x and couple them into the plane-parallel plate 21.1 perpendicularly to the used radiation. The plane-parallel plate 21.1 is heated by absorption in its material. In order to be able to set local heatings, a plurality of laser beams 44.x are oriented such that they meet at crossover points 45.x in the optically active region 22 of the plane-parallel plate 21.1, at which points the power density can be doubled, as a result of the absorption of two laser beams 44.1, 44.2. Only two laser beams 44.1, 44.2 intersecting at a crossover point 45 are illustrated in FIG. 2, for reasons of clarity. After the beams have passed through the plane-parallel plate 21.1, they are absorbed in light traps (not illustrated) and the heat is dissipated in a manner such that the excess energy does not heat other optical elements or other component parts such as, for example, mounts of the projection exposure apparatus. The input coupling points 42.x can be arranged at all four sides of the plane-parallel plates 21.x, in which case up to 200 laser beams can be coupled in per side, which in turn results in almost 800 adjustable degrees of freedom for correcting imaging aberrations.

In contrast to the optically active region 22, the region outside the optically active region 22, also referred to as edge region 23, is heated by electrical heating elements 25.x. The heating elements 25.x are arranged on the surface 24 of the lower plane-parallel plate 21.1 and each include a supply line 27.x, a heating structure 26.x and an outgoing line 28.x, the outgoing lines 28.x of the heating elements 25.x in the example shown all being connected to a common ground 29. In this case, the supply lines 27.x are embodied such that the electrical resistance is as low as possible in order to minimize unwanted heating in the region of the supply lines 27.x. The same also applies to the outgoing lines 28.x and the ground line 29. The heating structures 26.x are arranged in the regions in which heating by the heating elements 25.x is desired, the heating structures being distinguished by an increased resistance on account of a small cross section and/or a different material and being arranged in a specific region in a meandering fashion on the surface 24 of the plane-parallel plate 21.1. As a result, in the region of the heating structures 26.x the power density is higher by a multiple than in the region of the supply lines 27.x and outgoing lines 28.x and also the ground line 29. The supply lines 27.x all originate on a connection strip 30, which is arranged on the right-hand side of the plane-parallel plate 21.1 in FIG. 2. A fluid channel is embodied between the lower plane-parallel plate 21.1 and the upper plane-parallel plate 21.2 (not illustrated), air as cooling medium flowing through the fluid channel. The cooling gas flow 31 is indicated by three arrows in FIG. 2. The side elements of the cooling channel are not illustrated in FIG. 2, for reasons of clarity. The cooling medium serves as a heat sink which dissipates again the power introduced by the laser beams 44.x and the electrical heating elements 25.x and thus has a thermally neutral effect in relation to the other optical elements of the projection optical unit, with the result that only a temperature distribution within the plane-parallel plates is brought about which brings about the predetermined correction effect by way of the dependence of the refractive index on temperature. In the example shown, the plane-parallel plate 21.1 furthermore includes four temperature sensors 33.x, which are arranged outside the optically active region 22 and are illustrated merely schematically by circles in FIG. 2. On the basis of the values detected by the temperature sensors 33.x, the temperature distribution in the plate can be determined by an open-loop or closed-loop control (not illustrated). the temperature distribution is used for determining the power to be introduced by the electromagnetic heating radiation 44.x and the electrical heating elements 25.x. The powers thus determined are passed on to the open-loop control or closed-loop control of the lasers and of the heating elements, with the result that a predetermined temperature distribution is established in the plane-parallel plates 21.x.

### LIST OF REFERENCE SIGNS

1 Projection exposure apparatus
2 Wafer
3 Illumination device
4 Reticle stage
5 Reticle
6 Wafer stage
7 Projection lens
8 Optical element
9 Mount
10 Lens housing
11 Projection beam
20 Thermal manipulator (device)
21 Plane-parallel plate (optical element)
22 Optically active region
23 Edge region
24 Surface
25.x Heating elements
26.x Heating structure
27.x Supply line
28.x Outgoing line
29 Ground line
30 Connection strip
31 Cooling gas flow
32.1-32.2 Side surface
33.1-33.4 Temperature sensor
41.1-41.10 Optical waveguide
42.1-42.10 Input coupling points
43.1-43.10 Input coupling optical unit
44.1,44.2 Laser beam (electromagnetic heating radiation)
45 Crossover point

What is claimed is:

1. An apparatus, comprising:
an optical correction element comprising an optically active region;
a plurality of electrical heating elements supported by the optical correction element; and
an electromagnetic heating radiation source configured to provide electromagnetic heating radiation,
wherein:
the plurality of electrical heating elements is outside the optically active region;
during use of the apparatus:
is used light impinges on the optically active region;
the electromagnetic heating radiation at least partly irradiates the optically active region; and
the plurality of electrical heating elements provide locally adaptable densities of heating power depending heating of the optically active region due to the used light impinging on the optically active region and the electromagnetic heating radiation irradiating the optically active region; and
the apparatus is a semiconductor lithography projection exposure apparatus.

2. The apparatus of claim 1, wherein the apparatus does not have an electrical heating element supported by the optical correction element within the optically active region.

3. The apparatus of claim 1, wherein the plurality of electrical heating elements comprises a plurality of resistance wires.

4. The apparatus of claim 3, wherein the resistance wires are at least one micrometer thick.

5. The apparatus of claim 1, wherein the plurality of electrical heating elements is disposed on a surface of the optical correction element.

6. The apparatus of claim 1, wherein, for at least some of the heating elements, different heating elements have different electrical properties.

7. The apparatus of claim 1, further comprising an open-loop/closed-loop control configured to control the plurality of heating elements so that the plurality of electrical heating elements provide the locally adaptable densities of heating power.

8. The apparatus of claim 1, further comprising temperature sensor configured to detect a temperature of the optical correction element.

9. The apparatus of claim 1, wherein the optical correction element comprises a plane-parallel plate.

10. The apparatus of claim 9, wherein the plane-parallel plate has a thickness of from two millimeters to 20 millimeters.

11. The apparatus of claim 1, wherein the optical correction element comprises two plane-parallel plates, and a fluid channel is between the two plane-parallel plates.

12. The apparatus of claim 11, wherein the two plane-parallel plates are arranged parallel to one another at a distance of from 2 millimeters to 50 millimeters.

13. The apparatus of claim 11, wherein a material of the two plane-parallel plates and a wavelength of the electromagnetic heating radiation are configured so that an average absorbed power of the electromagnetic heating radiation over the optically active region is at least 10 Watts.

14. The apparatus of claim 11, wherein a material of the plane-parallel plates and a wavelength of the electromagnetic heating radiation are configured so that an absorptivity of the electromagnetic heating radiation over the optically active region is from 10% to 20% of an incident power of the electromagnetic heating radiation per 100 millimeters of the material.

15. The apparatus of claim 11, further comprising an electrical connection strip contacting the plurality of electrical heating elements, wherein at least sections of the electrical connection strip run parallel to the fluid channel.

16. The apparatus of claim 1, further comprising a common ground line, wherein at least two of the electrical heating elements are connected to the common ground line.

17. The apparatus of claim 1, wherein the used radiation is EUV radiation, and the electromagnetic heating radiation is infrared radiation.

18. The apparatus of claim 1, wherein a wavelength of the used radiation is from one nanometer to 30 nanometers.

19. The apparatus of claim 1, further comprising:
an illumination device configured to at least partially illuminate an object in an object plane with the used radiation; and
a projection device configured to image the object into an image plane,
wherein the projection device comprises the an optical correction element and the plurality of electrical heating elements.

20. An apparatus, comprising:
an optical correction element comprising an optically active region;
a plurality of heating elements supported by the optical correction element; and
an electromagnetic heating radiation source configured to provide electromagnetic heating radiation,
wherein:
the plurality of heating elements is outside the optically active region;
during use of the apparatus:
used light impinges on the optically active region;
the electromagnetic heating radiation at least partly irradiates the optically active region; and
the plurality of heating elements provide locally adaptable densities of heating power depending heating of the optically active region due to the used light impinging on the optically active region and the electromagnetic heating radiation irradiating the optically active region; and
the apparatus is a semiconductor lithography projection exposure apparatus.
